(19) United States
(12) Patent Application Publication
(10) Pub. No.: US 2015/0034842 A1
(43) Pub. Date: Feb. 5, 2015

(54) DRIVING APPARATUS, CHARGED PARTICLE BEAM IRRADIATION APPARATUS, METHOD OF MANUFACTURING DEVICE

(71) Applicant: CANON KABUSHIKI KAISHA, Tokyo (JP)

(72) Inventor: Shinji Uchida, Utsunomiya-shi (JP)

(21) Appl. No.: 14/444,893

(22) Filed: Jul. 28, 2014

(30) Foreign Application Priority Data
Jul. 31, 2013 (JP) 2013-159136

(51) Int. Cl. H01F 7/06; H01J 37/26; H01J 37/317

(52) U.S. Cl. CPC H01F 7/06; H01J 37/3174; H01J 37/26; H01J 2237/0264; H01J 2237/31715
USPC 250/492.3; 335/219

(57) ABSTRACT

A driving apparatus includes an electromagnetic actuator configured to generate a motive power by an electromagnetic force; a movable portion configured to be movable by the electromagnetic actuator; a magnetic shield unit that surrounds the electromagnetic actuator, wherein the magnetic shield unit includes a first magnetic shield having an opening and a second magnetic shield having an opening arranged in this order from a side closer to electromagnetic actuator. The opening opposes the second magnetic shield at least part of an area of the opening, and the movable portion is bent so as to penetrate through the openings of the first and the second magnetic shields.

### BACKGROUND OF THE INVENTION

1. Field of the Invention

This disclosure relates to a driving apparatus, a charged particle beam apparatus having the driving apparatus mounted thereon, and a method of manufacturing a device.

2. Description of the Related Art

In the case where mounting an electromagnetic actuator for driving an object on an apparatus susceptible to a magnetic field in the periphery thereof like a drawing apparatus and a brain magnetic field measurement device, a leakage of the magnetic field generating from the electromagnetic actuator needs to be restrained sufficiently.

Accordingly, Japanese Patent Laid-Open No. 2004-153151 describes an electromagnetic actuator configured to reduce a leakage of a magnetic field by arranging electromagnets in such orientations that magnetic poles thereof overlap with each other. There is also described a technology that reduces the leakage of the magnetic field to the outside by surrounding the electromagnetic actuator with a plurality of magnetic shields formed of a hollow member having openings which allow penetration of a rod-shaped movable portion for transmitting a force generated by the electromagnetic actuator to the object.

However, although the effect of reducing the leakage of the magnetic field is achieved by surrounding a major part of the electromagnetic actuator with a plurality of the magnetic shields, the leakage of the magnetic field still occurs by an opening of the inner magnetic field facing the opening of the outer magnetic field.

In the case of an electron beam drawing apparatus, there is a problem that the position of drawing a pattern may be deviated due to the influence of the magnetic field, so that a further reduction of the leakage of the magnetic field is required considering with recent miniaturization of the drawing pattern. In addition, the reduction of leakage of the magnetic field is an issue in the same manner in the case of a measurement apparatus handling a charged particle beam and apparatuses using imperceptible magnetic field.

### SUMMARY OF THE INVENTION

This disclosure provides a driving apparatus capable of driving an object and reducing a leakage of a magnetic field generated by an electromagnetic actuator via an opening of a magnetic shield.

A driving apparatus of this disclosure includes: an electromagnetic actuator: a movable portion configured to be movable by the electromagnetic actuator; and a magnetic shield unit that surrounds the electromagnetic actuator, and the magnetic shield unit includes a first magnetic shield having an opening and a second magnetic shield having an opening arranged in this order from a side closer to a magnetic field generating portion of the electromagnetic actuator, at least part of an area of the opening of the first magnetic shield opposes the second magnetic shield, and the movable portion is bent so as to penetrate through the openings of the first and the second magnetic shields.

Further features of the present invention will become apparent from the following description of exemplary embodiments with reference to the attached drawings.

### BRIEF DESCRIPTION OF THE DRAWINGS

FIG. 1 is a drawing illustrating a configuration of a drawing apparatus on which a driving apparatus according to a first embodiment is mounted.

FIG. 2 is a cross-sectional view of the driving apparatus according to the first embodiment.

FIG. 3 is a cross-sectional view of the driving apparatus according to a second embodiment.

FIG. 4 is a cross-sectional view of the driving apparatus 6 according to a third embodiment.

FIG. 5 is a cross-sectional view of the driving apparatus according to a fourth embodiment.

FIG. 6 is a cross-sectional view of the driving apparatus according to a fifth embodiment.

### DESCRIPTION OF THE EMBODIMENTS

A driving apparatus of this disclosure is an apparatus on which the driving apparatus is mounted, and may be applied to an apparatus required to reduce a leakage of a magnetic field from an electromagnetic actuator. Examples of the apparatus include an instruments using a charged particle beam (charged particle beam irradiation apparatus) such as an electron beam drawing apparatus and an electronic microscope, and include medical instruments such as a brain magnetic field measurement device (brain function measurement device) configured to measure brain function of a test subject by detecting a change of a magnetic field. The driving apparatus according to first to fifth embodiments applied to a drawing apparatus will be described as an example.

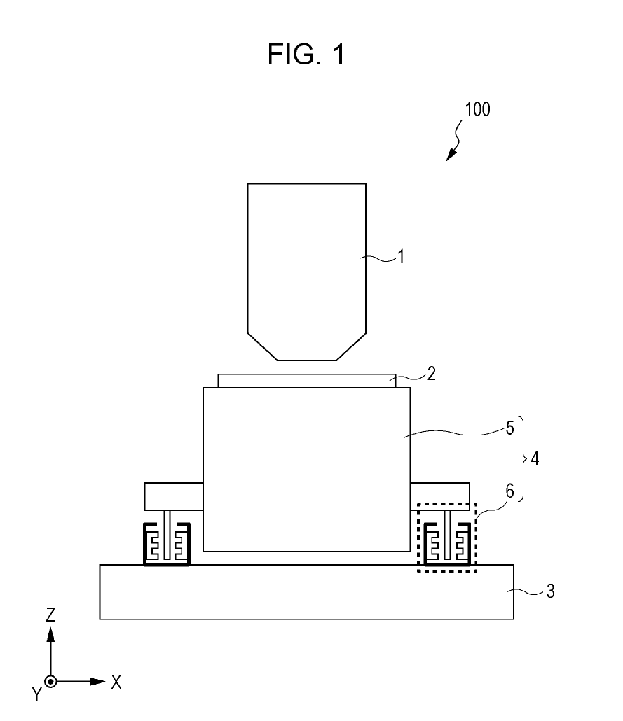

FIG. 1 is a drawing illustrating a configuration of a drawing apparatus 100 on which a driving apparatus according to a first embodiment is mounted. The drawing apparatus 100 in FIG. 1 is assumed to be capable of mounting driving apparatuses of respective embodiments described later instead of the driving apparatus 6 of the first embodiment. The drawing apparatus 100 includes a housing 1, a substrate 2 (irradiation target), a long stroke stage 3, and a short stroke stage 4. The housing 1 accommodates an electron source and an electronic optical system for irradiating an electron beam toward the substrate 2.

The short stroke stage 4 is placed on an upper surface of the long stroke stage 3, includes a supporting member 5 (object) which supports the substrate 2 and the driving apparatus 6 configured to provide the supporting member 5 with a driving force. The long stroke stage 3 performs rough positioning by moving the substrate 2 by a long stroke, and the supporting member 5 of the short stroke stage 4 performs a precise positioning by moving the substrate 2 by a short stroke.

A substrate holder (not illustrated) for holding the substrate 2 and a mirror (not illustrated) used for measuring the position of the supporting member 5 are installed on the supporting member 5. By reflecting a laser beam emitted by a laser interferometer (not illustrated) with the mirror, positions of the supporting member 5 in X, Y, and Z-axis directions are measured. The long stroke stage 3 and the supporting member 5 of the short stroke stage 4 are driven on the basis of measured positional information. In this manner, an intended pattern is drawn on the substrate 2 by irradiating the substrate 2 with the electron beam while driving the supporting member 5.

The drawing apparatus 100 having the configuration described above is installed in a vacuum chamber (not illustrated) having a vacuum internal atmosphere. The vacuum chamber is installed in a magnetic shielding room (not illustrated) to avoid an influence of the magnetic field from peripheral instruments such as an electric component rack (not illustrated) including a control substrate (not illustrated) for controlling the electron beam.

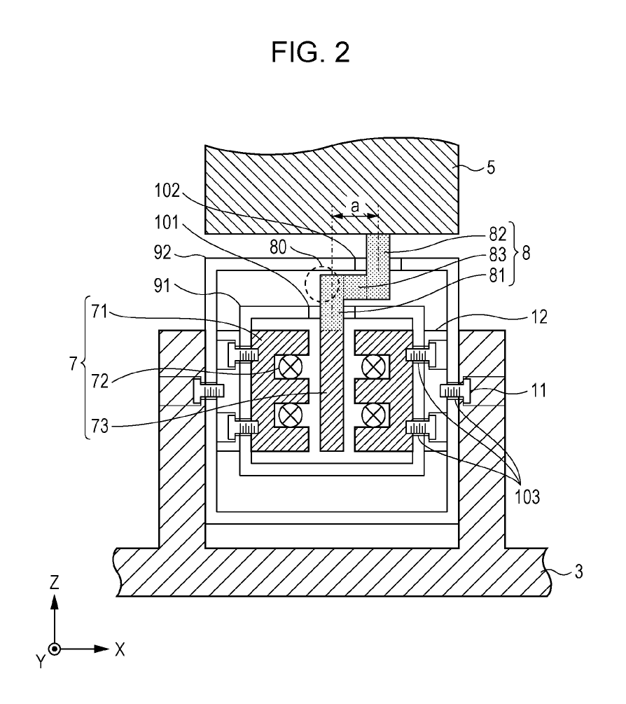

FIG. 2 is a cross-sectional view of the driving apparatus 6 according to the first embodiment. The driving apparatus 6 includes an electromagnet unit 7 mounted as an electromagnetic actuator for driving the supporting member 5 with an electromagnetic force. The electromagnet unit 7 includes an E-core 71 as a stator and an I-core 73 as a mover, both formed of a magnetic material. The electromagnet unit 7 includes a coil 72 configured to excite the E-core 71, and the I-core 73 moves upon reception of a magnetic attraction force generated between the I-core 73 and the excited E-core 71.

The intensity and the direction of the magnetic attraction force generated between the E-core 71 and the I-core 73 is controlled by controlling the magnitude and the direction of a current flowing in the coil 72. In order to achieve a reduction in weight of a movable portion of the short stroke stage 4, the I-core 73 is preferably lighter than the E-core 71. A merit of using the electromagnet unit 7 as the electromagnetic actuator is, for example, a high thrust efficiency per unit current.

In the first to the fourth embodiments, portion opposing the E-core 71 is described as the I-core 73. However, the length of the I-core 73 is not limited thereto. The I-core 73 may either be shorter or longer than the E-core 71 in the Z-axis direction as long as a length which generates a magnetic attraction force with respect to the excited E-core 71.

A transmitting member 8 is coupled at one end to the I-core 73 and at the other end to the supporting member 5. Therefore, the supporting member 5 moves in conjunction with the I-core 73 via the transmitting member 8 upon reception of the magnetic attraction force. In the case where the electromagnet unit 7 is arranged as illustrated in FIG. 2, the supporting member 5 moves in the X-axis direction. The transmitting member 8 is preferably a non-magnetic material for preventing a leakage of a magnetic field.

The driving apparatus 6 moves the supporting member 5 coupled to a movable portion via the movable portion which is movable by an electromagnetic force generated by the electromagnetic actuator. In other words, in the first embodiment and the second to the fourth embodiments described later, the I-core 73 and the transmitting member 8 correspond to the movable portions.

The supporting member 5 may be moved in six axes directions by mounting driving apparatus for moving in the Y-axis and Z-axis directions, which is not illustrated, in addition to the driving apparatus 6 for the movement in the X-axis direction illustrated in FIG. 2 on the drawing apparatus 100 in FIG. 1.

In order to prevent a leakage of the magnetic field generating from the electromagnet unit 7 to the outside, the electromagnet unit 7 is multiply surrounded by a plurality of the magnetic shields (the magnetic shield unit) having a hollow parallelepiped shape. A plurality of the magnetic shields include a magnetic shield 91 (first magnetic shield) having an opening 101 and a magnetic shield 92 (second magnetic shield) having an opening 102 are provided in the order from a magnetic field generating portion of the electromagnet unit 7, that is, from the side closer to the E-core 71 in this embodiment.

As a material of the magnetic shields 91 and 92, a soft magnetic material such as Permalloy is used. The soft magnetic material is a high magnetic permeability, and is a material superior in shielding performance that can trap the magnetic field in a closed space thereby.

In order to couple the magnetic shields 91 and 92 and the E-core 71 integrally, the magnetic shields 91 and 92 are provided with openings 103 for coupling. A spacer 12 formed of a non-magnetic material is provided between the magnetic shields 91 and 92. The E-core 71, the magnetic shield 91, the spacer 12 and the magnetic shield 92 are arranged in which sequence and coupled integrally by inserting a plurality of bolts 11 through the openings 103 for coupling. By forming the bolts 11 of a material having a high magnetic permeability, the leakage of the magnetic field from the openings 103 for coupling is reduced.

In addition to the openings 103, the opening 101 is provided in the magnetic shield 91, and the opening 102 is provided in the magnetic shield 92. The openings 101 and 102 are holes for allowing the transmitting member 8, formed to be coupled to the I-core 73 and the supporting member 5 integrally, to penetrate therethrough in a non-contact manner. A motive power generated by the electromagnet unit 7 is transmitted to the supporting member 5 by the transmitting member 8 penetrating through the openings 101 and 102. The openings 101 and 102 need to have a size which ensure a movable range of the supporting member 5, however, the larger the openings 101 and 102, the more the magnetic field leaks easily.

Accordingly, in order to reduce the leakage of the magnetic field form the magnetic shields 91 and 92, a center position of the opening 102 in the magnetic shield 92 is arranged so as to be shifted by a in the X-axis direction with respect to a center position of the opening 101 of the magnetic shield 91. By arranging the openings 101 and 102 so as to be shifted from each other, at least an area of the opening 101 partly opposes the magnetic shield 92, so that the magnetic field leaked outward of the magnetic shield 91 through the opening 101 is shielded by the magnetic shield 92. In this configuration, the leakage of the magnetic field from the opening 102 may be reduced.

Therefore, the area of the opening 101 opposing the magnetic shield 92 is preferably larger than the area of the opening 101 opposing the opening 102. In particular, as illustrated in FIG. 2, a configuration in which the opening 101 opposes only the magnetic shield 92 is preferable. It is because that an effect of reducing the leakage of the magnetic field is further increased in this configuration.

The transmitting member 8 includes a bent portion 80 in a space between the magnetic shields 91 and 92, and the bent portion 80 is formed by mechanically coupling linear-shaped coupling members 81, 82, and 83 with each other with the bolts 11 formed of a non-magnetic material. With the transmitting member 8 being bent, the openings 101 and 102 may be arranged at positions shifted in the X-axis direction, so that securement of the movable range of the supporting member 5 and reduction of the leakage of the magnetic field from the electromagnet unit 7 leaked out via the opening may be achieved simultaneously. Therefore, in the drawing apparatus according to the first embodiment, the deviation of the drawing position caused by the magnetic field from the electromagnet unit 7 is reduced in comparison with the case where the openings 101 and 102 are not shifted.

The term “bent” does not mean only a shape bent at a right angle as illustrated in FIG. 2, but may include a shape bent by a suitable angle which allows the transmitting member 8 to pass through the openings 101 and 102.

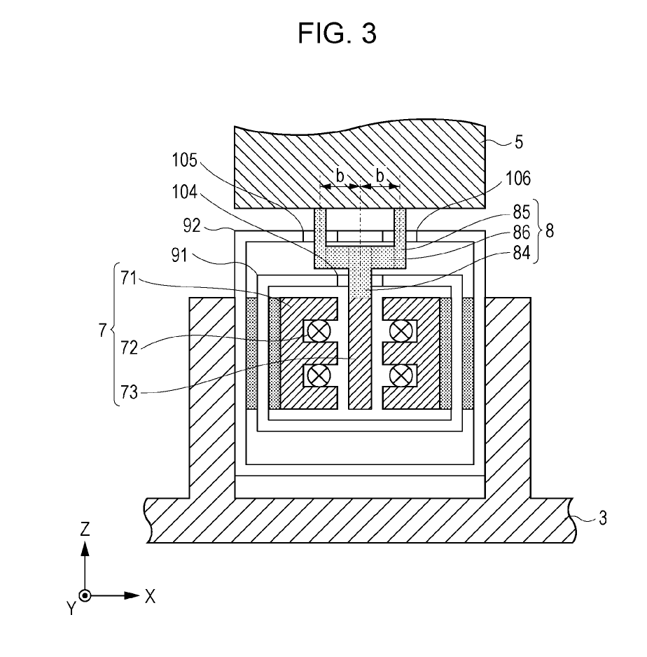

Referring now to FIG. 3, the driving apparatus 6 according to a second embodiment will be described. The driving apparatus 6 according to the second embodiment also includes the electromagnet unit 7, the magnetic shields 91 and 92, and the transmitting member 8. However, a method of coupling the E-core 71 of the electromagnet unit 7 and the magnetic shields 91 and 92, the position of the openings of the magnetic shields 91 and 92, and the configuration of the transmitting member 8 is different from the first embodiment.

First of all, the method of coupling the E-core 71 and the magnetic shield 91, and the method of coupling shield 91 and 92 will be described. In the second embodiment, these members are integrally coupled with an epoxy-based adhesive agent. Therefore, the magnetic shields 91 and 92 need not to be provided with the openings 103 for coupling as illustrated in FIG. 1 and an effect of further reducing the leakage of the magnetic field is achieved.

Subsequently, a configuration relating to the opening positions of the magnetic shields 91 and 92 will be described. The magnetic shield 91 is provided with one opening 104, and the magnetic shield 92 is provided with two openings 105 and 106. Center positions of the openings 105 and 106 are shifted by b from the center of the opening 104 in the X-axis direction.

Since the transmitting member 8 penetrates through the openings 104,105 and 106 in a non-contact manner, the transmitting member 8 includes a bent portion in the space between the magnetic shields 91 and 92. The bent portion is formed by coupling a coupling member 84 penetrating through the opening 104, two coupling members 85 penetrating respectively through the openings 105 and 106, and two coupling members 86 for coupling these coupling members.

In the same manner as the first embodiment, a center position of the opening 104 of the magnetic shield 91 and center positions of the opening 105 and the opening 106 of the magnetic shield 92 are shifted. Accordingly, the magnetic field leaked to the outside of the magnetic shield 91 is shielded by the magnetic shield 92 opposing the opening 104.

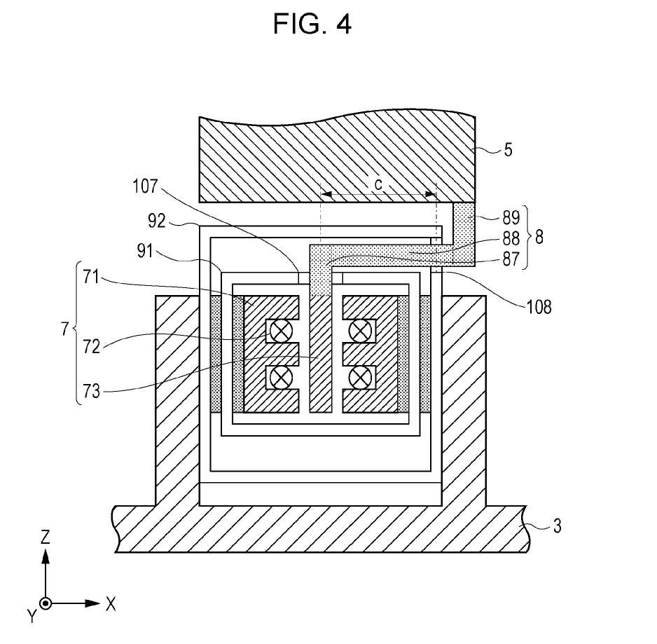

Referring now to FIG. 4, the driving apparatus 6 according to a third embodiment will be described. The third embodiment is a modification of the driving apparatus 6 of the second embodiment. The driving apparatus 6 of the third embodiment also includes the electromagnet unit 7, two layers of the magnetic shields 91 and 92 surrounding the electromagnet unit 7, and the transmitting member 8, and the E-core 71 and the magnetic shields 91 and 92 are coupled with an adhesive agent. However, the opening positions of the magnetic shields 91 and 92 and the configuration of the transmitting member 8 are different from the second embodiment.

In both the first embodiment and the second embodiment, the opening of the magnetic shield 92 is provided on a plane parallel to the magnetic shield 91, that is, on an upper surface of the magnetic shield 92. However, the third embodiment is different from the first and the second embodiments in that an opening 108 provided in the magnetic shield 92 is provided on a surface at a right angle with respect to a surface of the magnetic shield 91 having an opening 107, that is, on a side surface of the magnetic shield 92 (at a position apart from the mover than the stator).

In addition to the configurations of the openings 107 and 108 in the third embodiment, the structure of the transmitting member 8 penetrating through the opening 107 and 108 in a non-contact manner is also different from those in the first and second embodiments. A coupling member 87 penetrates through the opening 107, a coupling member 88 penetrates through the opening 108, and a coupling member 89 is coupled to the supporting member 5, and the coupling members 87 and 89 are coupled with the coupling member 88.

Center positions of the opening 107 and the opening 108 are apart from each other by c in the X-axis direction in this embodiment. The opening 108 is arranged at a position further from the I-core 73 than the E-core 71, and a shift amount between center positions of the opening 107 and the opening 108 is set to be maximized, whereby an effect of reduction of the leakage of the magnetic field may be improved.

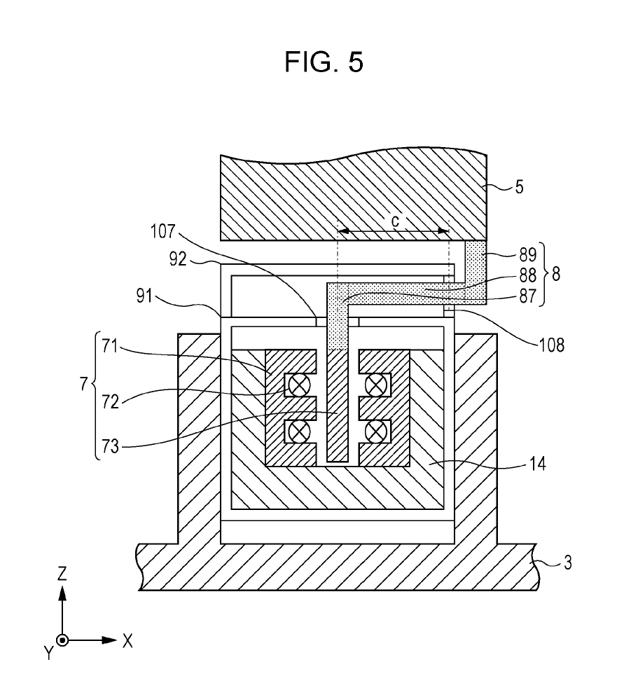

A fourth embodiment is different from other embodiments in configuration of the magnetic shield 92. FIG. 5 is a cross-sectional view of the driving apparatus 6 of the fourth embodiment. The fourth embodiment is the same as the respective embodiments described above in that the periphery of the electromagnet unit 7 is covered by the parallelepiped magnetic shield 91 having the opening 107, but is different in that the magnetic shield 92 has a parallelepiped shape in which one surface is missing so as to be capable of covering the magnetic shield 91.

The magnetic shield 92 includes the opening 108, and the arrangements of the opening 107 and the opening 108 is the same as the third embodiment. The E-core 71 is fixed with a fixing member 14 formed of a non-magnetic material so as not to come into contact with the magnetic shield 91. In the fourth embodiment, the magnetic shield 91 is superior in shielding property against the magnetic field, and is suitable for a case where only the leakage of the magnetic field near the opening is a concern.

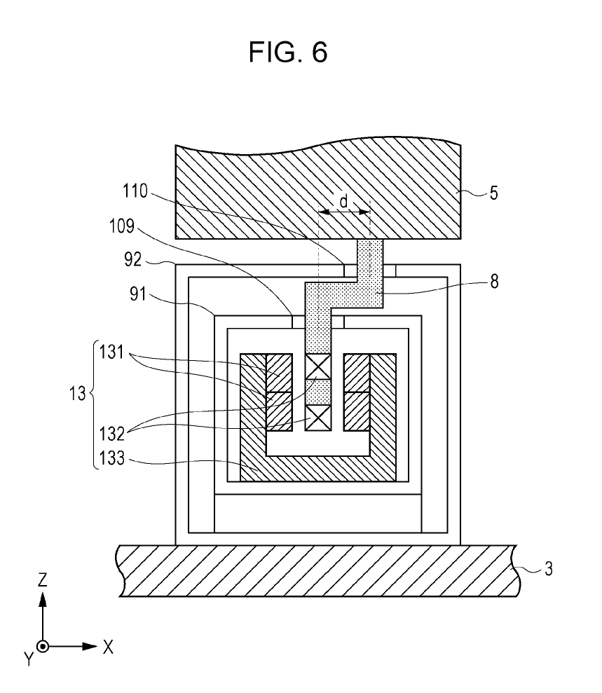

Referring now to FIG. 6, the driving apparatus 6 according to a fifth embodiment will be described. The driving apparatus 6 according to the fifth embodiment is different from those of the first to the fourth embodiments in that a linear motor unit 13 is used instead of the electromagnet unit 7.

The linear motor unit 13 is provided with permanent magnets 131 as stators, coils 132 as movers, and a yoke 133. The intensity and the direction of the magnetic attraction force generated between the permanent magnets 131 and the coils 132 are controlled by controlling the magnitude and the direction of a current flowing in the coils 132.

The coils 132 preferably has a form opposing the permanent magnets 131 as illustrated in FIG. 6. However, the coils 132 may be shifted to some extent from the position illustrated in FIG. 6 as long as a magnetic attraction force is generated with respect to the permanent magnets 131.

The transmitting member 8 is coupled at one end to the coils 132 and at the other end to the supporting member 5. Therefore, the supporting member 5 also moves in association therewith via the transmitting member 8 upon reception of the magnetic attraction force. From the definition described above, in this embodiment, the coils 132 and the transmitting member 8 are movable portions which can be moved by the electromagnetic actuator.

The linear motor unit 13 is also surrounded multiply by a plurality of the hollow magnetic shields 91 and 92 for reducing the leakage of the magnetic field in the same manner as the case where the electromagnet unit 7 is used. The magnetic shields 91 and 92 are arranged in this order from the position closer to the magnetic field generating portion of the linear motor unit 13, that is, from between the permanent magnets 131.

The magnetic shield 91 is provided with an opening 109, and the magnetic shield 92 is provided with an opening 110 in order to allow penetration of the transmitting member 8 coupled to the coils 132 in a non-contact manner therethrough. Furthermore, the openings 109 and 110 are arranged so that center positions are shifted by d in the X-axis direction for reducing leakage of the magnetic field from the openings 109 and 110. The transmitting member 8 has a bent portion in the same manner as the first embodiment.

The linear motor unit 13 has an advantage that a vibration cannot be transmitted easily to the substrate 2 in comparison with the case where the electromagnet unit 7 is used. Therefore, the linear motor unit 13 is suitable for drawing finer patterns in comparison with the first to the fourth embodiments.

By changing the arrangement of the permanent magnets 131, the driving direction of the coils 132 and the transmitting member 8, that is, the driving direction of the substrate 2 can be changed. In the configuration illustrated in FIG. 5, driving is allowed only in the coaxial direction. However, a configuration in which driving in given directions is allowed may be achieved by combining the linear motor units 13 for driving in the X, Y, and Z-axis direction in one driving apparatus 6.

Finally, other embodiments will be described. In the respective embodiments, examples in which only the transmitting member 8 penetrates through the openings formed in the magnetic shields 91 and 92 have been described. However, this disclosure is not limited thereto. What is essential is that the movable portion which can be moved by the electromagnetic actuator penetrate through the openings, and for example, a configuration in which a movable element including the I-core 73 penetrates through the openings is also applicable.

Movable portions which can be moved by the electromagnetic actuator like the I-core 73 and the transmitting member 8 or the coils 132 and the transmitting member 8 do not necessarily have to be configured by being combined with different materials, and may be integrally formed by using the same material. The costs required for assembly may be reduced by forming integrally.

The case where the two-layered magnetic shield 91 and 92 are used is exemplified, a configuration in which a magnetic shield having a plurality of layers is added to the outside of the magnetic shield 92, and the electromagnet unit is surrounded by the magnetic shield having three or more layers is also applicable. The shielding ratio of the magnetic field depends on the thicknesses of the magnetic shields 91 and 92 and the distance between the magnetic shields. Therefore, the configuration may be determined in view of these elements.

Although the case where the magnetic shields 91 and 92 have a hollow rectangular column shape has been exemplified, the magnetic shields 91 and 92 may be of a hollow members having curved surfaces as long as part of the area of the opening through which the transmitting member 8 penetrates opposes the magnetic shield.

In the respective embodiments, only the case where the openings are shift in the X-axis direction has been described. However, the shift may be in other directions (Y-axis direction, or a direction having an X-axis component and a Y-axis component). The driving direction of the supporting member 5 and the direction of shift of the openings do not have to be the same.

The openings 101 to 108 may be arranged on the long stroke stage 3 side with respect to the supporting member 5 of the short stroke stage 4. In addition to an effect of reducing the leakage of the magnetic field by shifting the two opening positions, an effect of preventing the electron beam from being affected by the magnetic field easily is achieved by positioning the two openings at positions as far from the substrate 2 as possible.

In the case where the driving apparatus 6 of the present invention is mounted on the electronic drawing apparatus, the driving apparatus 6 having the linear motor unit 13 as the electromagnetic actuator or the driving apparatus 6 having the electromagnet unit 7 as the electromagnetic actuator may be used concurrently.

The driving apparatus 6 according to all the embodiments described above are configured in such a manner that the center positions of the openings of the magnetic shields 91 and 92 are arranged so as to be shifted in a certain direction, and part of the area of the opening formed in the magnetic shield 91 opposes the magnetic shield 92. Accordingly, the object may be driven while reducing the leakage of the magnetic field generating from the electromagnetic actuator such as the electromagnet unit 7 and the linear motor unit 13.

Furthermore, by mounting the driving apparatus 6 according to the embodiments described above, on the short stroke stage 4 of the drawing apparatus 100, the influence of the magnetic field on the electron beam for drawing a latent image of the pattern is reduced, so that a phenomenon that the drawing position is deviated may be reduced.

### Method of Manufacturing Device

A method of manufacturing a device of this disclosure includes a process of irradiating a substrate on a supporting member configured to support the substrate with a charged particle beam while moving the supporting member by the driving apparatus described in the respective embodiments, and a process of developing the substrate on which a pattern is drawn. Furthermore, other known processes (oxidization, film formation, depositing, doping, flattening, etching, resist separation, dicing, bonding, packaging and the like) may also be included.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-159136, filed Jul. 31, 2013, which is hereby incorporated by reference herein in its entirety.

What is claimed is:

1. A driving apparatus comprising:
an electromagnetic actuator; and
a movable portion configured to be movable by the electromagnetic actuator; and
a magnetic shield unit that surrounds the electromagnetic actuator, wherein
the magnetic shield unit includes a first magnetic shield having an opening and a second magnetic shield having an opening arranged in this order from a side closer to a magnetic field generating portion of the electromagnetic actuator,
at least part of an area of the opening of the first magnetic shield opposes the second magnetic shield, and
the movable portion is bent to penetrate through the openings of the first and the second magnetic shields.

2. The driving apparatus according to claim 1, wherein
at least part of an area of the opening of the first magnetic shield opposes the second magnetic shield so a leakage of a magnetic field from the second magnetic field is reduced.

3. The driving apparatus according to claim 1, wherein
an area of the opening of the first magnetic shield opposing the second magnetic shield is larger than an area of the opening of the first magnetic shield opposing the opening of the second magnetic field.

4. The driving apparatus according to claim 1, wherein an entire area of the opening of the first magnetic shield opposes the second magnetic shield.

5. The driving apparatus according to claim 1, wherein the movable portion includes a mover of the electromagnetic actuator that is movable upon reception of a magnetic attraction force and a transmitting member that transmits a thrust generating from the mover to the object.

6. The driving apparatus according to claim 5, wherein the transmitting member includes a non-magnetic material.

7. The driving apparatus according to claim 5, wherein a stator of the electromagnetic actuator opposing the mover is adhered to the first magnetic shield with an adhesive agent.

8. The driving apparatus according to claim 5, wherein the opening of the second magnetic shield is located at a position that is farther from the mover than the stator.

9. The driving apparatus according to claim 5, wherein the mover and the transmitting member are formed integrally.

10. The driving apparatus according to claim 1, wherein the electromagnetic actuator is an electromagnet.

11. The driving apparatus according to claim 1, wherein the electromagnetic actuator is a linear motor.

12. A charged particle beam irradiation apparatus comprising: a movable object; and a driving apparatus configured to provide the object with a driving force, and being configured to irradiate an irradiation target on the object with a charged particle beam, wherein
the driving apparatus includes:
an electromagnetic actuator;
a magnetic shield unit that surrounds the electromagnetic actuator,
the magnetic shield unit includes a first magnetic shield having an opening and a second magnetic shield having an opening arranged in this order from a side closer to a magnetic field generating portion of the electromagnetic actuator,
at least part of an area of the opening of the first magnetic shield opposes the second magnetic shield, and
a movable portion configured to be movable by the electromagnetic actuator is bent so as to penetrate through the openings of the first and the second magnetic shields.

13. A method of manufacturing a device comprising:
irradiating a substrate as an irradiation target with a charged particle beam by using a driving apparatus; and
developing the substrate to be irradiated in the irradiating, wherein
the driving apparatus includes:
an electromagnetic actuator;
a magnetic shield unit that surrounds the electromagnetic actuator,
the magnetic shield unit includes a first magnetic shield having an opening and a second magnetic shield having an opening arranged in this order from a side closer to a magnetic field generating portion of the electromagnetic actuator,
at least part of an area of the opening of the first magnetic shield opposes the second magnetic shield, and
a movable portion configured to be movable by the electromagnetic actuator is bent so as to penetrate through the openings of the first and the second magnetic shields.
